(19) United States
(12) Patent Application Publication
(10) Pub. No.: US 2025/0048617 A1
(43) Pub. Date: Feb. 6, 2025

(54) CAPACITOR STRUCTURE

(71) Applicant: SAMSUNG ELECTRONICS CO., LTD., SUWON-SI (KR)

(72) Inventors: BYEUNGMOO KANG, Suwon-si (KR); SEOKHAN PARK, Suwon-si (KR); KISEOK LEE, Suwon-si (KR)

(21) Appl. No.: 18/736,153

(22) Filed: Jun. 6, 2024

(30) Foreign Application Priority Data
Aug. 2, 2023 (KR) 10-2023-0101035

(51) Int. Cl. H10B 12/00

(52) U.S. Cl. CPC H10B 12/315

(57) ABSTRACT

A capacitor structure may include a plurality of lower electrodes arranged in a first direction and a second direction perpendicular to the first direction, a supporter including a plurality of openings and adjoining the plurality of lower electrodes, a dielectric layer covering the supporter and the plurality of lower electrodes, and an upper electrode covering the dielectric layer, where each of the plurality of openings contacts four lower electrodes, and where the plurality of openings contact opposite sides of the plurality of lower electrodes along the first direction and the second direction.

### CROSS-REFERENCE TO RELATED APPLICATION

This application claims priority under 35 U.S.C. § 119 to Korean Patent Application No. 10-2023-0101035 filed on Aug. 2, 2023, in the Korean Intellectual Property Office and all the benefits accruing therefrom, the entire contents of which is incorporated herein by reference.

### BACKGROUND

### 1. Field

The present disclosure relates to a capacitor structure.

### 2. Description of the Related Art

As semiconductor devices become highly integrated, capacitors with higher capacitance within a limited area are of interest. As a method for increasing the capacitance of a capacitor, there are methods of increasing the surface area of an electrode, reducing the thickness of an equivalent oxide layer of a dielectric layer, or using a material having a high dielectric constant in the dielectric layer.

### SUMMARY

The present disclosure provides an approach to decrease bridging defects that occur when the bending directions of adjacent lower electrodes of the capacitor structure converge.

A capacitor structure may include a plurality of lower electrodes arranged in a first direction and a second direction perpendicular to the first direction, a supporter including a plurality of openings and adjoining the plurality of lower electrodes, a dielectric layer covering the supporter and the plurality of lower electrodes, and an upper electrode covering the dielectric layer, where each of the plurality of openings contacts four lower electrodes, and where the plurality of openings contact opposite sides of the plurality of lower electrodes along the first direction and the second direction.

A capacitor structure may include a plurality of lower electrodes horizontally arranged in a first direction and a second direction perpendicular to the first direction, a plurality of supporters adjoining the plurality of lower electrodes and spaced apart in a third direction perpendicular to the first direction and the second direction, a dielectric layer covering the plurality of supporters and the plurality of lower electrodes, and an upper electrode covering the dielectric layer, where the plurality of supporters include a plurality of openings penetrating along the third direction, where each of the plurality of openings contacts four lower electrodes, where the plurality of openings contact opposite sides of rows of lower electrodes arranged along the first direction, and contact opposite sides of columns of lower electrodes arranged along the second direction, and where a pattern of the plurality of openings included in each supporter overlaps in the third direction.

A capacitor structure may include a plurality of lower electrodes horizontally arranged in a first direction and a second direction perpendicular to the first direction, a plurality of supporters adjoining the plurality of lower electrodes, and spaced apart in a third direction perpendicular to the first direction and the second direction, a dielectric layer covering a plurality of supporters and the plurality of lower electrodes, and an upper electrode covering the dielectric layer, where the plurality of supporters includes a first supporter and a second supporter, where the first supporter may include a plurality of first openings having a linear shape extending in the first direction, and where the second supporter may include a plurality of second openings having a linear shape extending in the second direction.

According to embodiments, bridging defects that occur when the bending directions of adjacent lower electrodes of the capacitor structure converge may be decreased.

In addition, according to embodiments, spreadability of upper electrode and dielectric layer with respect to lower electrodes may be improved, the capacitance of the capacitor may be increased.

### BRIEF DESCRIPTION OF THE DRAWINGS

FIG. 1 is a top plan view of a capacitor structure of an embodiment.

FIG. 2 is a cross-sectional view taken along line A-A′ of FIG. 1.

FIG. 3A is an example of a cross-sectional view taken along line B-B′ of FIG. 1.

FIG. 3B is another example of a cross-sectional view taken along line B-B′ of FIG. 1.

FIG. 4A is an example of a cross-sectional view taken along line C-C′ of FIG. 1.

FIG. 4B is another example of a cross-sectional view taken along line C-C′ of FIG. 1.

FIG. 5 is a top plan view of a capacitor structure of another embodiment.

FIG. 6 is a cross-sectional view taken along line A-A′ of FIG. 5.

FIG. 7 is a cross-sectional view taken along line B-B′ of FIG. 5.

FIG. 8 is a top plan view of a capacitor structure of another embodiment.

FIG. 9 is an example of a perspective view of a capacitor structure of FIG. 8.

FIG. 10 is a cross-sectional view taken along line A-A′ of FIG. 9.

FIG. 11 is a cross-sectional view taken along line B-B′ of FIG. 9.

FIG. 12 is a cross-sectional view taken along line C-C′ of FIG. 9.

FIG. 13 is a cross-sectional view taken along line D-D′ of FIG. 9.

FIG. 14 is another example of a perspective view of a capacitor structure 100 of FIG. 8.

FIG. 15 is a drawing showing various examples of a planar shape of an opening of a supporter.

FIG. 16 is an example of a cross-sectional view taken along line I-I′ of FIG. 1.

### DETAILED DESCRIPTION

A method for increasing the surface area of the electrode involves increasing the height of the lower electrode, but in this case, the lower electrode may be tilted or collapsed accordingly. To prevent this, a supporter capable of supporting the lower electrode can be used.

The present disclosure will be described more fully hereinafter with reference to the accompanying drawings, in which embodiments of the disclosure are shown. As those skilled in the art would realize, the described embodiments may be modified in various different ways without departing from the spirit or scope of the present disclosure and claims.

In describing the various embodiments of the present invention, parts or portions of the embodiments may be omitted may be omitted for clarity. The identical or similar constituent elements throughout the specification are denoted by the same reference numerals.

In addition, in the drawings, the size and thickness of each element are arbitrarily illustrated for ease of description, and the present disclosure is not necessarily limited to those illustrated in the drawings. The thicknesses of layers, films, panels, regions, areas, etc., may be exaggerated for clarity.

It will be understood that when an element, such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of other elements.

Furthermore, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

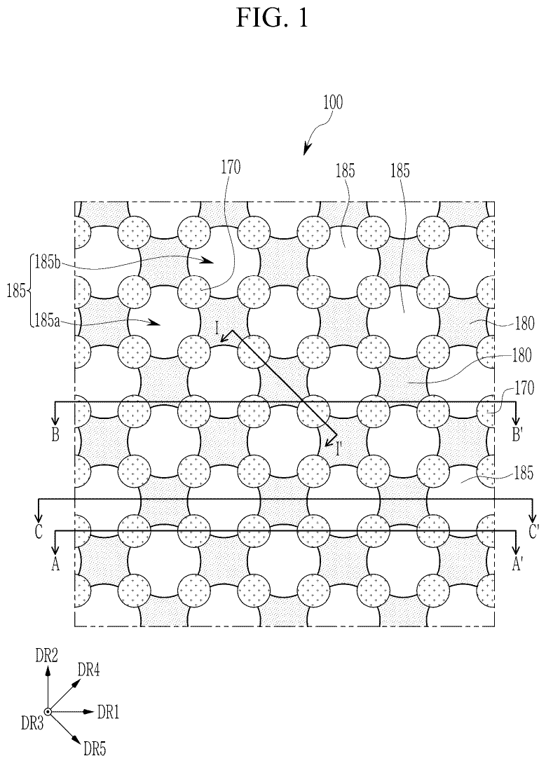

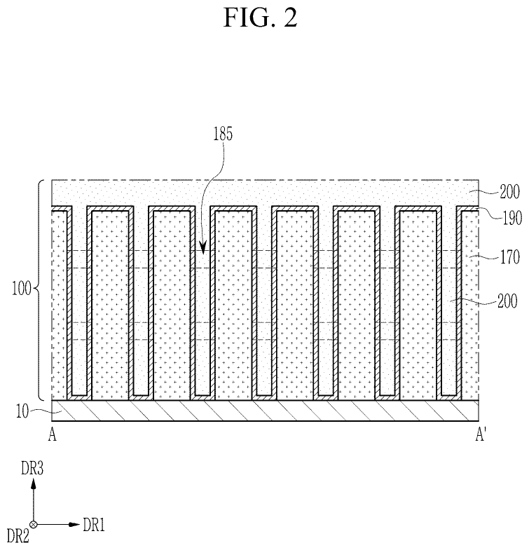

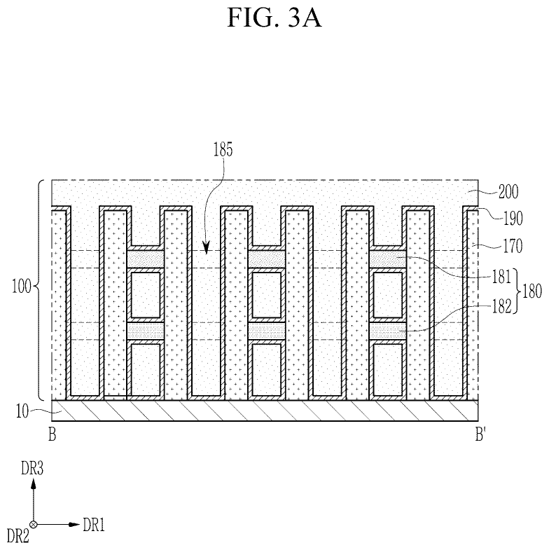

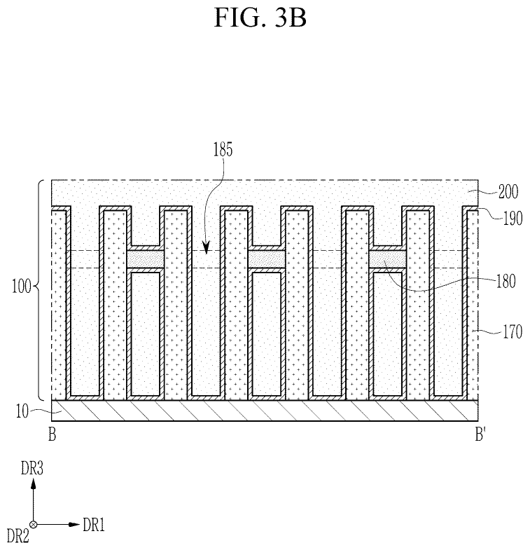

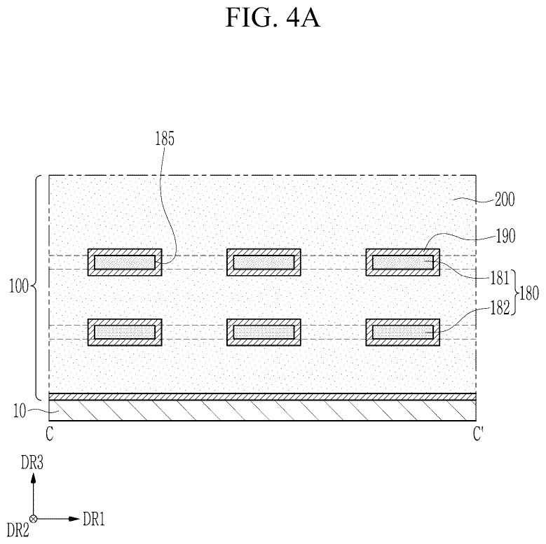

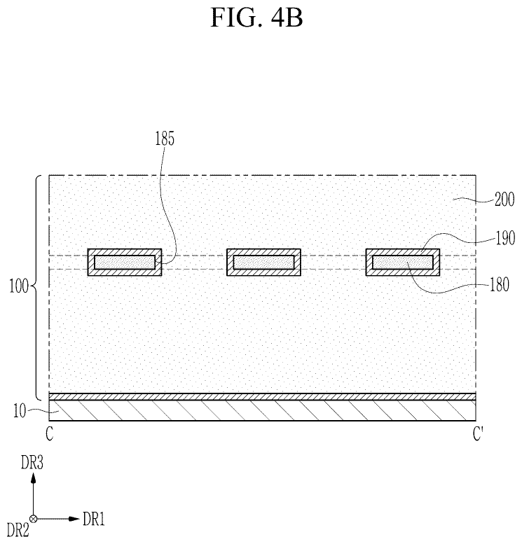

FIG. 1 is a top plan view of a capacitor structure 100 of an embodiment. FIGS. 2 to 4b is a cross-sectional view of the capacitor structure 100 of FIG. 1. FIG. 2 is a cross-sectional view taken along line A-A′ of FIG. 1. FIG. 3A is an example of a cross-sectional view taken along line B-B′ of FIG. 1. FIG. 3B is another example of a cross-sectional view taken along line B-B′ of FIG. 1. FIG. 4A is an example of a cross-sectional view taken along line C-C′ of FIG. 1. FIG. 4B is another example of a cross-sectional view taken along line C-C′ of FIG. 1.

Referring to FIG. 1 to FIG. 4B, the capacitor structure 100 may include a plurality of lower electrodes 170, a supporter 180, a dielectric layer 190, and an upper electrode 200. The capacitor structure 100 may be positioned on a lower structure 10, where the capacitor structure 100 and the lower structure 10 may overlap in a third direction DR3. The lower structure 10 may include a semiconductor substrate, semiconductor devices, and insulation layers. The capacitor structure 100 may be electrically connected to semiconductor devices of the lower structure 10.

In order to show the supporter 180 or pattern of a plurality of openings 185 included in the supporter 180, FIG. 1 omits the lower structure 10, the dielectric layer 190, and the upper electrode 200, for convenience.

Referring to FIG. 1, the plurality of lower electrodes 170 may be arranged in a first direction DR1 and a second direction DR2 crossing the first direction DR1, in a plan view, where the second direction DR2 may be perpendicular to the first direction DR1. The plurality of lower electrodes 170 may be arranged side by side along the first direction DR1, where the lower electrodes 170 may be spaced apart in the first direction DR1. The plurality of lower electrodes 170 may be arranged side by side along the second direction DR2, where the lower electrodes 170 may be spaced apart in the second direction DR2. The plurality of lower electrodes 170 may be disposed horizontally apart from each other. The plurality of lower electrodes 170 may be two-dimensionally arranged on the lower structure 10, where the lower electrodes 170 arranged in the first direction DR1 and the second direction DR2 can form a grid array.

As shown in FIG. 2, each of the plurality of lower electrodes 170 may extend along the first direction DR1 and the third direction DR3 perpendicular to the second direction DR2. The lower electrode 170 may be, for example, in a pillar shape, but is not limited thereto. As another example, the lower electrode 170 may have a hollow pillar shape, with one end of the pillar being closed and the other end being open. A bottom surface of each of the plurality of lower electrodes 170 may contact the lower structure 10.

As shown in FIG. 1, a planar shape of the lower electrode 170 may have a circular shape, but it is not limited thereto. The lower electrodes 170 may have various shapes, such as an elliptical shape, a polygon, or a rounded polygon.

Referring to FIG. 1, the supporter 180 may surround the plurality of lower electrodes 170. The supporter 180 may have a plurality of openings 185 which expose portions of the sidewalls of some lower electrodes. The supporter 180 may be formed to surround a portion of side surfaces of the plurality of lower electrodes 170. The supporter 180 may have a thickness in the first direction DR1 and the third direction DR3 perpendicular to the second direction DR2. The supporter 180 may support the plurality of lower electrodes 170 having a high aspect ratio to prevent the lower electrodes 170 from bending or falling down.

In various embodiments, the supporter 180 may include the plurality of openings 185, where the plurality of openings 185 may extend through the supporter 180 along the third direction DR3 perpendicular to the first direction DR1 and the second direction DR2. The supporter 180 may be a mesh or openwork structure adjoining each of the lower electrodes 170, where the supporter 180 may include a plurality of portions interrupted by and located between the lower electrodes 170. As the number of the openings 185 increases, the area which the upper electrode 200 and the dielectric layer 190 are deposited on the plurality of lower electrodes 170 may be expanded.

In an embodiment, each of the plurality of openings 185 may contact four lower electrodes 170, where the openings 185 can expose a portion of a sidewall of each of the adjoining lower electrodes 170. The four lower electrodes 170 contacting one opening 185 may be located at vertex positions of a quadrangle. The four lower electrodes 170 contacting one opening 185 may be form a 2×2 matrix arranged in the first direction DR1 and the second direction DR2.

In an embodiment, the plurality of openings 185 may contact alternating sides of the rows of lower electrodes 170 arranged along the first direction DR1. In an embodiment, the plurality of openings 185 may contact alternating sides of columns of lower electrodes arranged along the second direction DR2. The plurality of openings 185 may be positioned in a zigzag pattern based on rows or columns of the lower electrodes, where adjacent openings 185 along a diagonal direction DR4 and DR5 to the first and second directions are separated by a lower electrode 170.

In various embodiments, a planar shape of the plurality of openings 185 may have a shape of a circle, a quadrangle, or a quadrangle with rounded corners, but is not limited thereto.

In an embodiment, each of the plurality of lower electrodes 170 may contact at least one opening 185, where some lower electrodes 170 may contact two openings 185 in an oblique direction with respect to the first direction DR1 and the second direction DR2. In an embodiment, two openings 185a and 185b may be arranged to commonly contact one lower electrode 170 in a fourth direction DR4 oblique with respect to the first direction DR1 and the second direction DR2, and a fifth direction DR5 crossing the fourth direction DR4, where the fifth direction DR5 may be perpendicular to the fourth direction DR4. The plurality of openings 185 may be arranged along the fourth direction DR4 and the fifth direction DR5. The plurality of openings 185 may alternate along the fourth direction DR4 with the plurality of lower electrodes 170. The plurality of openings 185 may alternate along the fifth direction DR5 with the plurality of lower electrodes 170.

In an embodiment, the plurality of openings 185 may be spaced apart without interposing the lower electrode 170 in the first direction DR1, where the openings 185 may be separated by the supporters 180 along the first direction DR1. The plurality of openings 185 may be spaced apart without interposing the lower electrode 170 in the second direction DR2, where the openings 185 may be separated by the supporters 180 along the second direction DR2. Another lower electrode 170 may not exist between the lower electrodes 170 contacting each of the two openings 185 neighboring in the first direction DR1 or the second direction DR2.

In an embodiment, the supporter 180 may include a plurality of portions positioned between four lower electrodes 170 having a quadrangular arrangement. The portions may include a first portion and a second portion that are adjacent along the first direction DR1 or the second direction DR2, where the first portion and the second portion may be separated by an opening 185. For example, if a region surrounded by four lower electrodes having a quadrangular arrangement is referred to as a cell, the plurality of openings 185 may be spaced apart by one cell in the first direction DR1 and one cell in the second direction DR2.

In various embodiments, the supporter 180 may include, for example, silicon nitride, silicon nitride oxide, silicon boron nitride (SiBN), or silicon carbonitride (SiCN), but it is not limited thereto.

In an embodiment, two lower electrodes 170 neighboring in the first direction DR1 or the second direction DR2 may commonly contact one opening 185. For example, the opening 185 commonly contacting the two lower electrodes 170 neighboring in the first direction DR1 may also contact each of the two lower electrodes 170 and the two lower electrodes 170 neighboring in the second direction DR2. For example, the opening 185 commonly contacting the two lower electrodes 170 neighboring in the second direction DR2 may also contact each of the two lower electrodes 170 and the two lower electrodes 170 neighboring in the first direction DR1.

In an embodiment, each of the plurality of lower electrodes 170 may contact two openings 185. For example, the lower electrode 170 may commonly contact a first opening 185a and a second opening 185b. Although FIG. 1 illustrates that the first opening 185a and the second opening 185b are arranged along the fourth direction DR4, the two openings 185 contacting one lower electrode 170 may be arranged along the fourth direction DR4 or the fifth direction DR5. In an embodiment, a direction from a center of the first opening 185a contacting the lower electrode 170 to a center of the lower electrode 170 and a direction from a center of the second opening 185b contacting the lower electrode 170 to the center of the lower electrode 170 may be opposite to each other.

In various embodiments, a side surface of the lower electrode 170 may be asymmetrically oxidized depending on whether it is covered by the supporter 180. Due to this asymmetric oxidation, a bending force may act on the side surface of the lower electrode 170 in a direction parallel to a direction from a center of the opening 185 contacting the lower electrode 170 to the center of the lower electrode 170, in a plan view. For example, directions of two forces acting on the side surface of the lower electrode 170 contacting the two openings 185 in the directions from the center of the openings 185 to the center of the lower electrode 170 may be opposite to each other, which may result in uneven bending forces. However, two forces acting in opposite direction may cancel each other out, and the lower electrode 170 may not be bent in either direction. Such a result may be unknow at the time of fabrication.

Referring to FIG. 2 to FIG. 4B, the dielectric layer 190 may cover the supporter 180 and the plurality of lower electrodes 170. The dielectric layer 190 may cover the lower structure 10.

In various embodiments, the dielectric layer 190 may include a metal oxide having a high dielectric constant. The dielectric layer 190 may include, for example, at least one of zirconium oxide, hafnium oxide, titanium oxide, tantalum oxide, lanthanum oxide, aluminum oxide, yttrium oxide, strontium titanium oxide, or barium strontium titanium oxide, but is not limited thereto.

In various embodiments, the upper electrode 200 may cover the dielectric layer 190. The dielectric layer 190 may be positioned between and separate the lower electrode 170 and an upper electrode 190. The lower electrode 170 may be electrically separated from the upper electrode 190 by the dielectric layer 190. The upper electrode 200 may be integrally formed to cover the plurality of lower electrodes 170 and the interposing dielectric layer 190.

In various embodiments, the lower electrode 170 and the upper electrode 200 may include, for example, at least one of a metal, such as polysilicon, ruthenium (Ru), titanium (Ti), tantalum (Ta), niobium (Nb), iridium (Ir), molybdenum (Mo), tungsten (W), a conductive metal nitride, such as metal silicide, titanium nitride (TiN), tantalum nitride (TaN), niobium nitride (NbN), molybdenum nitride (MoN), tungsten nitride (WN), or a conductive metal oxide, such as iridium oxide IrO2, ruthenium oxide RuO2, strontium ruthenium oxide (SrRuO3), but is not limited thereto.

Referring to FIG. 2, the plurality of lower electrodes 170 may be spaced apart from each other on the lower structure 10 along the first direction DR1. A plurality of lower electrodes 170 may also be spaced apart from each other on the lower structure 10 along the second direction DR2. The dielectric layer 190 may be formed on the plurality of lower electrodes 170 and intervening portions of the lower structure 10. The dielectric layer 190 may cover the upper surfaces and the side surfaces of the plurality of lower electrodes 170, and cover the lower structure 10 exposed between the lower electrodes 170.

In various embodiments, the upper electrode 200 may be formed on the dielectric layer 190. The upper electrode 200 may be spaced apart from the lower electrode 170 and the lower structure 10 with the dielectric layer 190 therebetween. The upper electrode 200 may be above and extend across the upper surfaces of the plurality of lower electrodes 170.

Referring to FIG. 3A and FIG. 4A, the supporter 180 may include a first supporter 181 and a second supporter 182 surrounding the plurality of lower electrodes 170, as shown e.g., in FIG. 3A. The first supporter 181 and the second supporter 182 may be spaced apart in the third direction DR3 perpendicular to the first direction DR1 and the second direction DR2, where the first supporter 181 may be a greater distance from an upper surface of the lower structure 10 than the second supporter 182. A lower surface of the second supporter 182 may be positioned at a higher level than the upper surface of the lower structure 10 in the third direction DR3, and a lower surface of the first supporter 181 may be positioned at a higher level than an upper surface of the second supporter 182 in the third direction DR3. An upper surface of the first supporter 181 may be positioned at a lower level than the upper surfaces of the lower electrodes 170 in the third direction DR3.

FIG. 3A and FIG. 4A illustrate that two supporters 180 are provided, but is not limited thereto. Referring to FIG. 3B and FIG. 4B, in another embodiment, the number of the supporter 180 of the capacitor structure 100 may be one. In a still another embodiment, the number of the supporters 180 of the capacitor structure 100 may be three or more, where the additional supporter(s) 180 may further include at least one supporter spaced apart from the first supporter 181 and the second supporter 182 in the third direction DR3.

Referring to FIG. 3A and FIG. 3B, the lower electrodes 170 may be positioned on opposite sides of the supporter 180. A side surface of the supporter 180 may be in physical contact with the side surfaces of the lower electrodes 170 neighboring in the first direction DR1. The side surface of the supporter 180 may also contact the side surfaces of the lower electrodes 170 neighboring in the second direction DR2. In FIG. 3A, the first supporter 181 may contact side surfaces of upper portions of the lower electrodes 170 in the third direction DR3. The second supporter 182 may contact side surfaces of central portions of the lower electrodes 170 in the third direction DR3.

Referring to FIG. 3A and FIG. 3B, the dielectric layer 190 may cover an upper surface and a lower surface of the supporter 180. The dielectric layer 190 may cover the side surface of the lower electrode 170 positioned above the supporter 180 and the side surface of the lower electrode 170 positioned below the supporter 180 in the third direction DR3. The dielectric layer 190 may form a contiguous layer that extends from the side surface of the lower electrode 170 onto the upper surface and lower surface of the supporter 180. The dielectric layer 190 may extend from the upper surface and lower surface of the supporter 180 onto the side surfaces of the lower electrodes 170 adjoining the lower electrode 170 in the first direction DR1 and the second direction DR2.

In FIG. 3A, the dielectric layer 190 may cover the upper surfaces and lower surfaces of the first supporter 181 and the second supporter 182. The dielectric layer 190 may cover the side surface of the lower electrode 170 positioned above the first supporter 181 and the side surface of the lower electrode 170 positioned below the second supporter 182 in the third direction DR3. The dielectric layer 190 may cover the side surface of the lower electrode 170 positioned between the first supporter 181 and the second supporter 182 in the third direction DR3. The dielectric layer 190 may extend from the side surface of the lower electrode 170 onto the upper surfaces and the lower surfaces of the first supporter 181 and the second supporter 182. The dielectric layer 190 may extend from the upper surfaces and the lower surfaces of the first supporter 181 and the second supporter 182 onto the side surfaces of the lower electrodes 170 adjacent to the lower electrode 170 in the first direction DR1 and the second direction DR2.

Referring to FIG. 3A and FIG. 3B, the upper electrode 200 may be formed on the dielectric layer 190. The upper electrode 200 may be spaced apart and separated from the lower electrode 170, the supporter 180, and the lower structure 10 by the dielectric layer 190. The upper electrode 200 may overlap the upper surfaces and the side surfaces of the plurality of lower electrodes 170, the upper surface and lower surface of the supporter 180, including the first supporter 181 and the second supporter 182, and the upper surface of the lower structure 10 interposing the dielectric layer 190.

Referring to FIG. 4A and FIG. 4B, the supporter 180 may include the plurality of openings 185 penetrating along the third direction DR3 perpendicular to the first direction DR1 and the second direction DR2. In FIG. 4A, each of the first supporter 181 and the second supporter 182 may include the plurality of openings 185. Patterns of the plurality of openings 185 included in each of the first supporter 181 and the second supporter 182 may overlap in the third direction DR3.

In various embodiments, the supporter 180 may include portions spaced apart in the first direction DR1, where the supporter 180 may also include portions spaced apart in the second direction DR2 interposing the opening 185. The portions may be located between four lower electrodes 170 having a quadrangular arrangement in a plan view.

In FIG. 4A, each of the first supporter 181 and the second supporter 182 may include portions spaced apart in the first direction DR1 and separated by the opening 185. Each of the first supporter 181 and the second supporter 182 may include portions spaced apart in the second direction DR2 and separated by another opening 185. Each of the portions of the first supporter 181 and each of the portions of the second supporter 182 may contact with the four lower electrodes 170 having a quadrangular arrangement in a plan view. The portions of the first supporter 181 and the portions of the second supporter 182 may each form a separate layer that overlaps in the third direction DR3, respectively.

Referring to FIG. 4A and FIG. 4B, the dielectric layer 190 may cover the upper surface and lower surface of the portions of the supporter 180 separated by the openings 185 along the first direction DR1 and the second direction DR2. The dielectric layer 190 may cover side surfaces of the portions of the supporter 180 positioned on both sides of the openings 185. The dielectric layer 190 may extend from the upper surface and lower surface of the supporter 180 onto the side surface of the supporter 180 exposed by the openings 185. The dielectric layer 190 may cover the upper surface of the lower structure 10.

In FIG. 4A, the dielectric layer 190 may cover the portions of the first supporter 181 and upper surfaces and lower surfaces of the portions of the second supporter 182 separated by the openings 185 along the first direction DR1 and the second direction DR2. The dielectric layer 190 may cover the portions of the first supporter 181 and side surfaces of the portions of the second supporter 182 positioned on the both sides of the openings 185. The dielectric layer 190 may extend from the upper surfaces and the lower surfaces of the first supporter 181 and the second supporter 182 onto a side surface of the first supporter 181 and the second supporter 182 exposed by the openings 185.

The upper electrode 200 may be positioned on the dielectric layer 190. The upper electrode 200 may be spaced apart from the supporter 180 and the lower structure 10 by the dielectric layer 190. The upper electrode 200 may overlap upper surface, lower surface, and side surface of the supporter 180, and the upper surface of the lower structure 10 interposing the dielectric layer 190. In FIG. 4A, the upper electrode 200 may overlap the upper surface, the lower surface, and the side surface of the first supporter 181 and the second supporter 182, and the upper surface of the lower structure 10 interposing the dielectric layer 190.

According to the various embodiments described above with reference to FIG. 1 to FIG. 4B, an open ratio of the supporter 180 may be increased. The open ratio of the supporter 180 may be, for example, the ratio of the area of the supporter 180 to the area of the openings 185. As the open ratio of the supporter 180 increases, the area which the upper electrode 200 and the dielectric layer 190 are deposited on the plurality of lower electrodes 170 may be expanded.

In various embodiments, by dispersing (or cancelling) directions in which the side surfaces of the plurality of adjacent lower electrodes 170 are bent due to asymmetric oxidation, the bridging defects caused by the side surfaces of the plurality of adjacent lower electrodes 170 getting closer may be decreased.

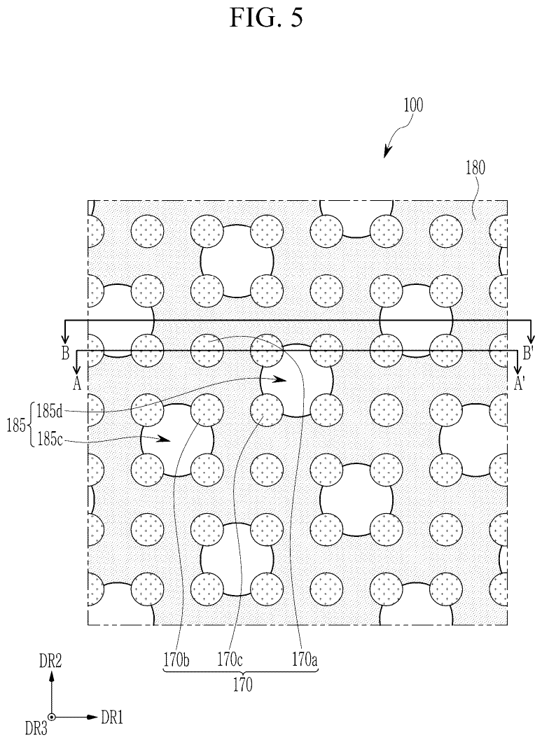

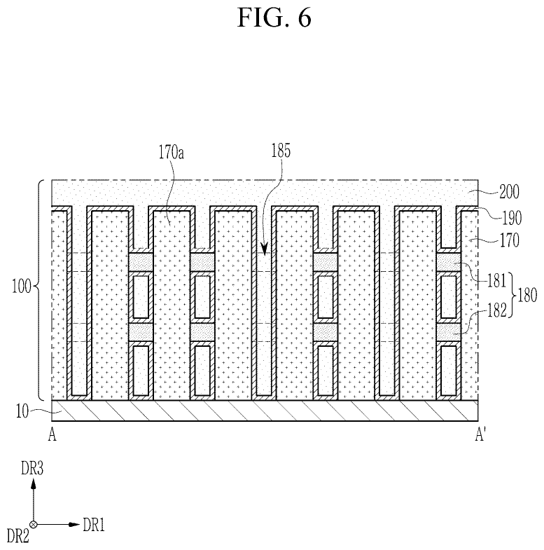

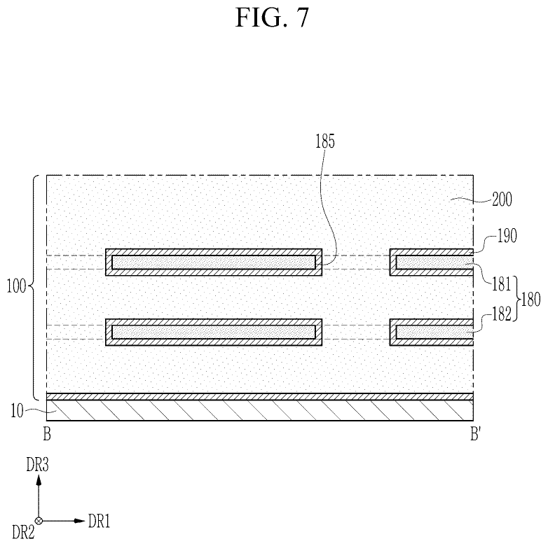

FIG. 5 is a top plan view of the capacitor structure 100 of another embodiment. FIG. 6 and FIG. 7 is a cross-sectional view of the capacitor structure 100 of FIG. 5. FIG. 6 is a cross-sectional view taken along line A-A′ of FIG. 5. FIG. 7 is a cross-sectional view taken along line B-B′ of FIG. 5.

Hereinafter, differences from the capacitor structure 100 of FIG. 1 will be mainly described. In order to show the supporter 180 or pattern of the plurality of openings 185 included in the supporter 180, FIG. 5 omits the lower structure 10, the dielectric layer 190, and the upper electrode 200, for convenience and clarity.

Referring to FIG. 5, the plurality of lower electrodes 170 may be arranged in the first direction DR1 and the second direction DR2 crossing the first direction DR1, in a plan view, where the second direction DR2 may be perpendicular to the first direction DR1. The plurality of lower electrodes 170 may be spaced apart from each other along the first direction DR1 and arranged side by side. The plurality of lower electrodes 170 may be spaced apart from each other along the second direction DR2 and arranged side by side. A planar shape of the lower electrode 170 may be, for example, circular, but is not limited thereto.

In various embodiments, the supporter 180 may surround the plurality of lower electrodes 170, where the supporter 180 may form a mesh or openwork structure. The supporter 180 may have a thickness in the first direction DR1 and the third direction DR3 perpendicular to the second direction DR2. The supporter 180 may include the plurality of openings 185 forming an openwork. The plurality of openings 185 may extend through the supporter 180 along the third direction DR3 perpendicular to the first direction DR1 and the second direction DR2. The planar shape of the plurality of openings 185 may have a shape of a circle, a quadrangle, or a quadrangle with rounded corners, but is not limited thereto.

In various embodiments, the plurality of openings 185 may alternately contact both sides of lower electrodes arranged in rows along the first direction DR1. The plurality of openings 185 may alternately contact both sides of lower electrodes arranged in columns along the second direction DR2. Each of the plurality of openings 185 may contact the four lower electrodes 170, where the four lower electrodes 170 contacting one opening 185 may be disposed in a 2×2 matrix form in the first direction DR1 and the second direction DR2. The supporter 180 can physically separate adjacent openings 185 and the lower electrodes 170 around the adjacent openings 185.

In an embodiment, the plurality of lower electrodes 170 may include isolated lower electrodes 170a that do not contact the opening 185, where the lower electrodes 170 may be located at the intersections of a square lattice. The supporter 180 may surround the isolated lower electrodes 170a, and extend along a circumference of a side surface of the isolated lower electrode 170a.

In an embodiment, the plurality of lower electrodes 170 may include the isolated lower electrodes 170a alternating with the four lower electrodes 170 contacting the opening 185 in the first direction DR1 and the second direction DR2. The isolated lower electrodes 170a may be spaced apart from the four lower electrodes 170 in the first direction DR1. The isolated lower electrodes 170a may be spaced apart from the four lower electrodes 170 in the second direction DR2.

In various embodiments, the four lower electrodes 170 between the isolated lower electrodes 170a adjacent in the first direction DR1 or the second direction DR2 may contact the opening 185, respectively. A neighboring pair of lower electrodes 170 among the four lower electrodes 170 may commonly contact the first opening, and another neighboring pair of two lower electrodes 170 may commonly contact the second opening. The first opening and the second opening may be positioned on both sides of the four lower electrodes, respectively.

In an embodiment, the plurality of openings 185 may be arranged and spaced apart in the first direction DR1. In an embodiment, the plurality of openings 185 may be arranged and spaced apart in the second direction DR2. The six lower electrodes 170 between the lower electrodes 170 contacting each of the parallel openings 185 in the first direction DR1 or the second direction DR2 may be arranged in a 2×3 format. For example, the six lower electrodes 170 located between the parallel openings 185 in the first direction DR1 may be disposed by three in the first direction DR1, by two in the second direction DR2. For example, the six lower electrodes 170 located between the parallel openings 185 in the second direction DR2 may be disposed by three in the second direction DR2, by two in the first direction DR1.

In an embodiment, the plurality of lower electrodes 170 may include a first lower electrode 170b and an adjacent second lower electrode 170c contacting different openings 185. FIG. 5 illustrates that the first lower electrode 170b and the second lower electrode 170c are an adjacent pair of lower electrodes 170 in the first direction DR1, but the same may be equally applied to two lower electrodes neighboring in the second direction DR2 and contacting different openings 185. A direction from a center of a first opening 185c contacting the first lower electrode 170b to a center of the first lower electrode 170b and a direction from a center of a second opening 185d contacting the second lower electrode 170c to a center of the second lower electrode 170c may be opposite to each other.

In various embodiments, the side surface of the lower electrode 170 may be asymmetrically oxidized depending on whether it is covered by the supporter 180. Due to this asymmetric oxidation, a bending force may act on the side surface of the lower electrode 170 in a direction parallel to a direction from the center of the opening 185 contacting the lower electrode 170 to the center of the lower electrode 170, in a plan view. For example, a side surface of the first lower electrode 170b may be bent in a direction parallel to a direction from a center of the first opening 185c to the center of the first lower electrode 170b. A side surface of the second lower electrode 170c may be bent in a direction parallel to a direction from a center of the second opening 185d to the center of the second lower electrode 170c. Since the direction from the center of the first opening 185c to the center of the first lower electrode 170b and the direction from the center of the second opening 185d to the center of the second lower electrode 170c are opposite to each other, the side surface of the first lower electrode 170b and the side surface of the second lower electrode 170c may not come close to each other even if they are bent. That is, by dispersing directions in which the side surfaces of the plurality of adjacent lower electrodes 170 are bent due to asymmetric oxidation, the bridging defects caused by the side surfaces of the plurality of adjacent lower electrodes 170 getting closer may be decreased.

Referring to FIG. 6, the plurality of lower electrodes 170 may be disposed apart from each other on the lower structure 10 along the first direction DR1. The plurality of lower electrodes 170 may also be disposed apart from each other on the lower structure 10 along the second direction DR2.

In various embodiments, the supporter 180 may include the first supporter 181 and the second supporter 182 surrounding the plurality of lower electrodes 170. The first supporter 181 and the second supporter 182 may be spaced apart in the third direction DR3 perpendicular to the first direction DR1 and the second direction DR2, where the first supporter 181 may be a greater distance from an upper surface of the lower structure 10 than the second supporter 182. FIG. 6 and FIG. 7 illustrate that two supporters 180 are provided, but it is not limited thereto, and the number of the supporters 180 may be one or three or more. For example, when the number of the supporters 180 is three or more, the capacitor structure 100 may further include at least one additional supporter spaced apart from the first supporter 181 and the second supporter 182 in the third direction DR3. The description of the supporter 180 to be described below may be equally applied to the case that there is one supporter 180, and when there are three or more supporters 180, the same may be applied to additional supporters as well as the first supporter 181 and the second supporter 182.

Referring to FIG. 6, the lower electrodes 170 may be positioned on the both sides of the supporter 180. The side surface of the supporter 180 may contact the side surfaces of the adjacent lower electrodes 170 in the first direction DR1. The side surface of the supporter 180 may contact the side surfaces of the lower electrodes 170 neighboring in the second direction DR2.

Referring to FIG. 6, the plurality of lower electrodes 170 may include the isolated lower electrode 170a on both sides of which the supporter 180 is positioned. Referring to FIG. 5, the supporter 180 may extend around the circumference of the side surface of the isolated lower electrode 170a.

In various embodiments, the dielectric layer 190 may cover the upper surfaces and the side surfaces of the plurality of lower electrodes 170. The dielectric layer 190 may cover the upper surface of the lower structure 10 positioned between the lower electrodes 170. The dielectric layer 190 may cover the upper surface and lower surface of the supporter 180. In FIG. 6, the dielectric layer 190 may cover the upper surfaces and the lower surfaces of the first supporter 181 and the second supporter 182.

In various embodiments, the upper electrode 200 may be formed on the dielectric layer 190. The upper electrode 200 may be spaced apart and separated from the lower electrode 170, the supporter 180, and the lower structure 10 by the dielectric layer 190. The upper electrode 200 may overlap the upper surfaces and the side surfaces of the plurality of lower electrodes 170, the upper surface and lower surface of the supporter 180, and the upper surface of the lower structure 10 interposing the dielectric layer 190. In FIG. 6, the upper electrode 200 may overlap the upper surfaces and the side surfaces of the plurality of lower electrodes 170, the upper surfaces and the lower surfaces of the first supporter 181 and the second supporter 182, and the upper surface of the lower structure 10 interposing the dielectric layer 190.

Referring to FIG. 7, the supporter 180 may include the plurality of openings 185 penetrating along the third direction DR3 perpendicular to the first direction DR1 and the second direction DR2. Each of the first supporter 181 and the second supporter 182 may include the plurality of openings 185. Patterns of the plurality of openings 185 included in each of the first supporter 181 and the second supporter 182 may overlap in the third direction DR3.

Referring to FIG. 7, the plurality of openings 185 may be spaced apart in the first direction DR1. Referring further to FIG. 5, the plurality of openings 185 may also be spaced apart in the second direction DR2. For example, the plurality of lower electrodes 170 may be disposed in a 2×3 matrix form between the openings 185 adjacent in the first direction DR1 or the second direction DR2.

In various embodiments, the dielectric layer 190 may cover the upper surface and lower surface of the supporter 180. The dielectric layer 190 may cover the side surface of the supporter 180 positioned on the both sides of the openings 185. The dielectric layer 190 may extend from the upper surface and lower surface of the supporter 180 onto the side surface of the supporter 180 exposed by the openings 185. The dielectric layer 190 may cover the upper surface of the lower structure 10.

In FIG. 7, the dielectric layer 190 may cover the upper surfaces and the lower surfaces of the first supporter 181 and the second supporter 182. The dielectric layer 190 may cover the side surfaces of the first supporter 181 and the second supporter 182 positioned on the both sides of the openings 185. The dielectric layer 190 may extend from the upper surfaces and the lower surfaces of the first supporter 181 and the second supporter 182 onto the side surface of the first supporter 181 and the second supporter 182 exposed by the openings 185.

In various embodiments, the upper electrode 200 may be formed on the dielectric layer 190. The upper electrode 200 may be spaced apart and separated from the supporter 180 and the lower structure 10 by the dielectric layer 190. The upper electrode 200 may overlap upper surface, lower surface, and side surface of the supporter 180, and the upper surface of the lower structure 10 interposing the dielectric layer 190. In FIG. 7, the upper electrode 200 may overlap the upper surface, the lower surface, and the side surface of the first supporter 181 and the second supporter 182, and the upper surface of the lower structure 10 interposing the dielectric layer 190.

In various embodiments, the capacitor structure 100 may have the same cross-section as FIG. 6 and FIG. 7 in the second direction DR2. The above description with reference to FIG. 6 and FIG. 7 may be equally or similarly applied to cross-sections cut parallel to the second direction DR2.

According to the embodiments described above with reference to FIG. 5 to FIG. 7, the open ratio of the supporter 180 may be increased. As the open ratio of the supporter 180 increases, spreadability of the upper electrode 200 and the dielectric layer 190 with respect to the plurality of lower electrodes 170 may be improved.

According to an embodiment described above, by dispersing directions in which the side surfaces of the plurality of adjacent lower electrodes 170 are bent due to asymmetric oxidation, the bridging defects caused by the side surfaces of the plurality of adjacent lower electrodes 170 getting closer may be decreased.

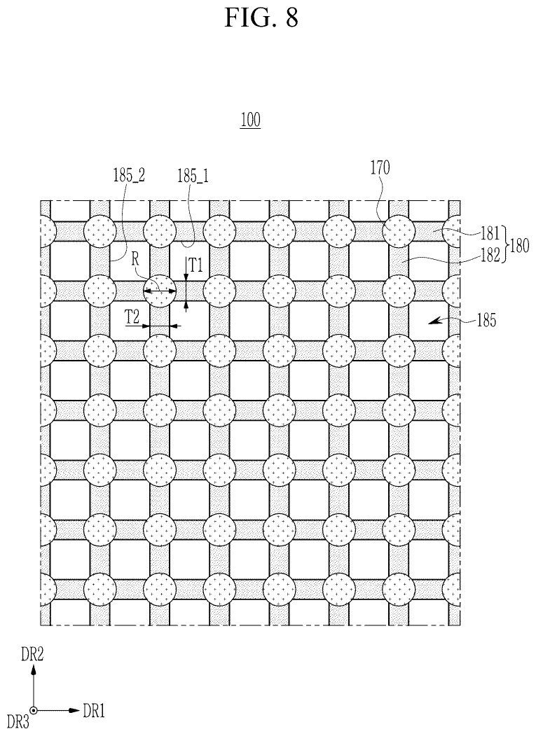

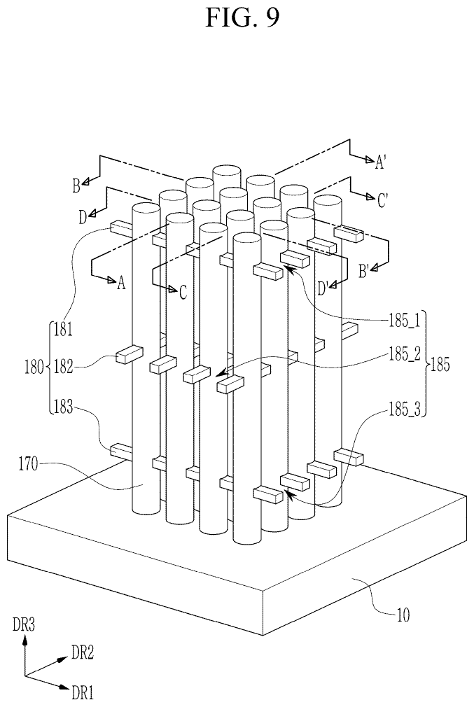

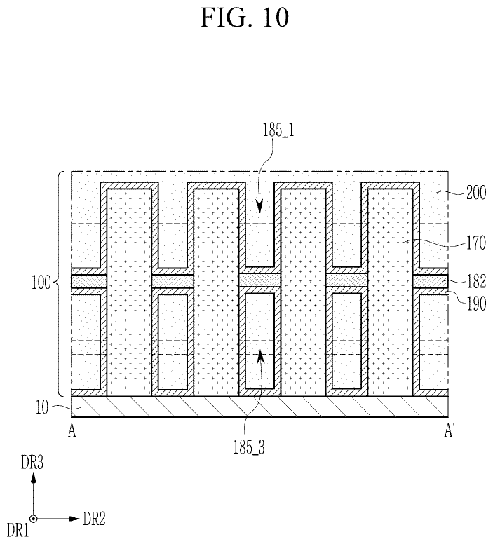

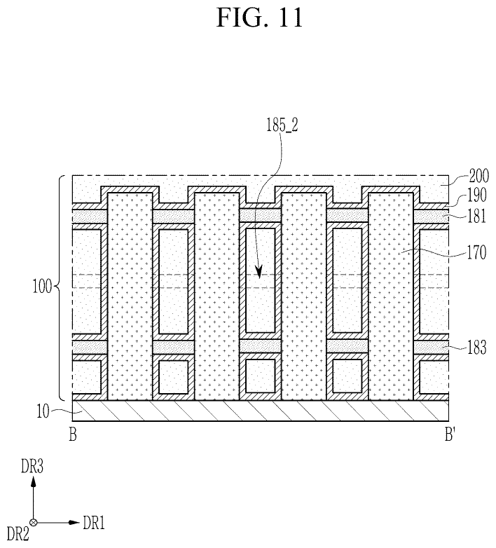

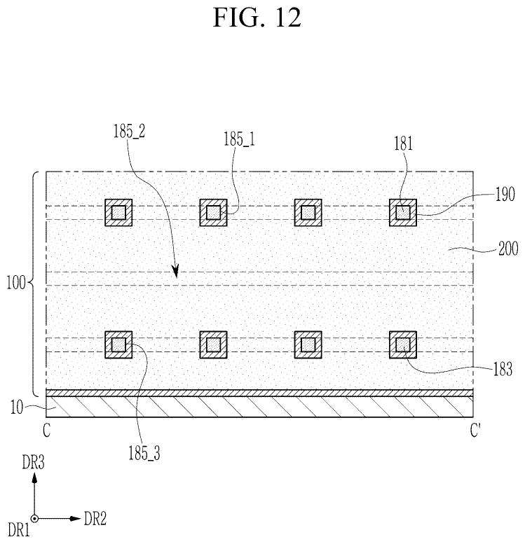

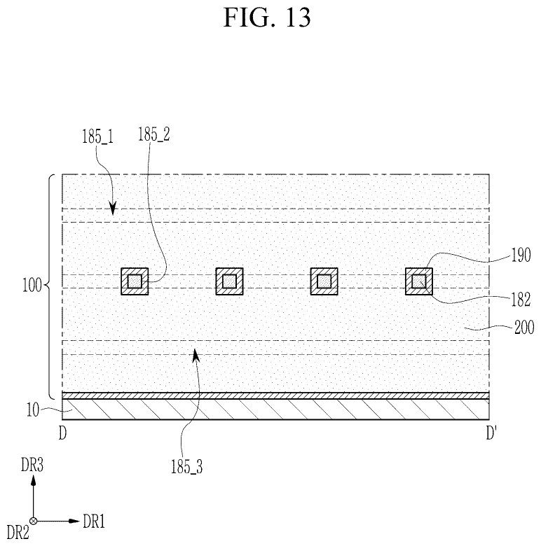

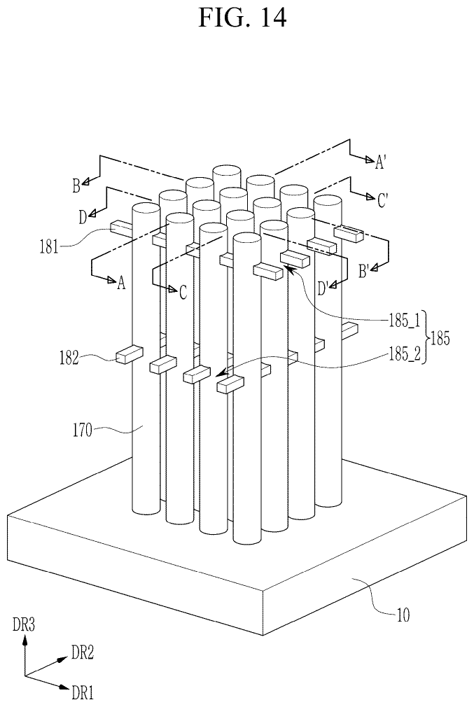

FIG. 8 is a top plan view of the capacitor structure 100 of another embodiment. FIG. 9 is an example of a perspective view of the capacitor structure 100 of FIG. 8. FIG. 10 is a cross-sectional view taken along line A-A′ of FIG. 9. FIG. 11 is a cross-sectional view taken along line B-B′ of FIG. 9. FIG. 12 is a cross-sectional view taken along line C-C′ of FIG. 9. FIG. 13 is a cross-sectional view taken along line D-D′ of FIG. 9. FIG. 14 is another example of a perspective view of the capacitor structure 100 of FIG. 8.

Referring to FIG. 8 to FIG. 14, the capacitor structure 100 may include the plurality of lower electrodes 170, a plurality of supporters 180, the dielectric layer 190, and the upper electrode 200. The capacitor structure 100 may be positioned on the lower structure 10. The capacitor structure 100 and the lower structure 10 may overlap in the third direction DR3. The lower structure 10 may include a semiconductor substrate, semiconductor devices, and insulation layers. The capacitor structure 100 may be electrically connected to semiconductor devices of the lower structure 10.

In order to show the supporter 180 or pattern of the plurality of openings 185 included in the supporter 180, FIG. 8 may omit the lower structure 10, the dielectric layer 190, and the upper electrode 200, for convenience and clarity. In order to show the supporter 180 or pattern of the plurality of openings 185 included in the supporter 180, FIG. 9 and FIG. 14 omit the dielectric layer 190 and the upper electrode 200, for mere convenience.

Referring to FIG. 8, FIG. 9, and FIG. 14, the plurality of lower electrodes 170 may be horizontally arranged in the first direction DR1 and the second direction DR2 crossing the first direction DR1, and extend in the third direction to form a pillar-like shape. For example, the second direction DR2 may be perpendicular to the first direction DR1. The plurality of lower electrodes 170 may be spaced apart from each other along the first direction DR1 and arranged side by side in a grid-like array. The plurality of lower electrodes 170 may be spaced apart from each other along the second direction DR2 and arranged side by side in a grid-like array.

Each of the plurality of lower electrodes 170 may extend along the third direction DR3 perpendicular to the first direction DR1 and the second direction DR2. The lower electrode 170 may be, for example, in a pillar shape, but is not limited thereto. As another example, the lower electrode 170 may have a hollow cylinder shape with one end closed. The bottom surface of each of the plurality of lower electrodes 170 may contact the upper surface of the lower structure 10. The upper surface of the lower structure 10 may be parallel to the plane formed by the first direction DR1 and the second direction DR2.

As shown in FIG. 8, a planar shape of the lower electrode 170 may have a circular shape, but it is not limited thereto, and it may have various shapes such as an elliptical shape, a polygon, or a rounded polygon.

In various embodiments, the plurality of supporters 180 may surround the plurality of lower electrodes 170. Each of the plurality of supporters 180 may be formed on a portion of the side surfaces of the plurality of lower electrodes 170. Each of the plurality of supporters 180 may have a thickness in the third direction DR3.

In various embodiments, the plurality of supporters 180 may be spaced apart in the third direction DR3 perpendicular to the first direction DR1 and the second direction DR2. For example, as shown in FIG. 14, the plurality of supporters 180 may include the first supporter 181 and the second supporter 182 spaced apart in the third direction DR3, but is not limited thereto, and the plurality of supporters 180 may include three or more supporters 180. As shown in FIG. 9, the plurality of supporters 180 may further include a third supporter 183 spaced apart from the first supporter 181 and the second supporter 182 in the third direction DR3.

In various embodiments, each of the plurality of supporters 180 may include the plurality of openings 185. In an embodiment, a planar shape of the plurality of supporters 180 may be a mesh shape, where the supporters 180 and openings form an openwork. Patterns of the plurality of openings 185 included in each of the plurality of supporters 180 disposed along the third direction DR3 may alternately overlap. For example, when the first supporter 181, the second supporter 182, and the third supporter 183 are disposed along the third direction DR3, the pattern of the plurality of openings 185 included in the first supporter 181 and the pattern of the plurality of openings 185 included in the third supporter 183 may overlap. Hereinafter, the description on the plurality of openings 185 included in the first supporter 181 and the first supporter 181 may be equally applied to the description on the plurality of openings 185 included in the third supporter 183.

In an embodiment, the first supporter 181 may include a plurality of first openings 185_1 having a linear shape extending in the first direction DR1, as shown e.g., in FIG. 8. The second supporter 182 may include a plurality of second openings 185_2 having a linear shape extending in the second direction DR2, as shown e.g., in FIG. 8. The plurality of first openings 185_1 and the plurality of second openings 185_2 may penetrate the first supporter 181 and the second supporter 182 in the third direction DR3, respectively. The first supporter 181 may include portions spaced apart along the second direction DR2 by the plurality of first openings 185_1. The second supporter 182 may include portions spaced apart along the first direction DR1 by the plurality of second openings 185_2.

In an embodiment, the first opening 185_1 may contact both sides of the lower electrodes 170 in the second direction DR2. The second opening 185_2 may contact the both sides of the lower electrodes 170 in the first direction DR1. The side surfaces of the lower electrodes 170 adjoining the first opening 185_1 and the second opening 185_2 may be exposed. The dielectric layer 190 and the upper electrode 200 may be positioned on the exposed side surface of the lower electrodes 170.

For example, an interval T1 of the first openings 185_1 may be shorter than a diameter R of the lower electrode 170, as shown e.g., in FIG. 8, but is not limited thereto. An interval T2 of the second openings 185_2 may be shorter than the diameter R of the lower electrode 170, as shown e.g., in FIG. 8, but is not limited thereto. As the interval T1 of the first openings 185_1 and the interval T2 of the second openings 185_2 are shorter than the diameter R of the lower electrode 170, an area where the side surfaces of the lower electrodes 170 are exposed may increase. As an exposed area of the side surfaces of the lower electrodes 170 increases, the area which the upper electrode 200 and the dielectric layer 190 are deposited on the lower electrodes 170 may be expanded, and the capacitance of the capacitor may be increased. An interval between the first openings may be shorter than a diameter of the lower electrode; and an interval between the second openings may be shorter than the diameter of the lower electrode.

In an embodiment, the first supporter 181 may connect the plurality of lower electrodes 170 along the first direction DR1. The first supporter 181 may be spaced apart from each other along the first direction DR1, and may connect between the plurality of lower electrodes 170 arranged side by side. The first supporter 181 may be positioned on both sides of the plurality of lower electrodes 170 in the first direction DR1, and may contact the side surfaces of the plurality of lower electrodes 170.

In an embodiment, the second supporter 182 may connect the plurality of lower electrodes 170 along the second direction DR2. The second supporter 182 may be spaced apart from each other along the second direction DR2, and may connect between the plurality of lower electrodes 170 arranged side by side. The second supporter 182 may be positioned on the both sides of the plurality of lower electrodes 170 in the second direction DR2, and may contact the side surfaces of the plurality of lower electrodes 170.

In an embodiment, the first supporter 181 may include supporters of a rod shape extending in the first direction DR1, as shown e.g., in FIG. 9. The supporters of a rod shape extending in the first direction DR1 may be spaced apart from each other along the second direction DR2. The first opening 185_1 may be positioned between supporters of a rod shape extending in the first direction DR1.

In an embodiment, the second supporter 182 may include supporters of a rod shape extending in the second direction DR2, as shown e.g., in FIG. 9. The supporters of a rod shape extending in the second direction DR2 may be spaced apart from each other along the first direction DR1. The second opening 185_2 may be positioned between supporters of a rod shape extending in the second direction DR2.

In an embodiment, the plurality of supporters 180 may alternately include supporters of a rod shape extending in the first direction DR1 and supporters of a rod shape extending in the second direction DR2 in the third direction DR3. Referring to FIG. 9, for example, the first supporter 181, the second supporter 182, and the third supporter 183 may be disposed along the third direction DR3, the first supporter 181 may include supporters of a rod shape extending in the first direction DR1, the second supporter 182 may include supporters of a rod shape extending in the second direction DR2, and the third supporter 183 may include supporters of a rod shape extending in the first direction DR1.

In various embodiments, shape and pattern of each of the plurality of supporters 180 disposed along the third direction DR3 may alternately overlap in the third direction DR3. Accordingly, even if the number of the supporters 180 is three or more, in a plan view like FIG. 8, only an upper surface of an uppermost first supporter 181 in the third direction DR3 among the supporters 180 having the same shape and pattern as the first supporter 181 and an upper surface of an uppermost second supporter 182 in the third direction DR3 among the supporters 180 having the same shape and pattern as the second supporter 182 may be seen. For example, the third supporter 183 may not be shown in a plane view.

Referring to FIG. 9, the capacitor structure 100 may include the first supporter 181, the second supporter 182, and the third supporter 183 that are spaced apart in the third direction DR3. The upper surface of the first supporter 181 may be positioned at a lower level than an upper surface of the plurality of lower electrodes 170 in the third direction DR3. The upper surface of the second supporter 182 may be positioned at a lower level than the lower surface of the first supporter 181 in the third direction DR3. An upper surface of the third supporter 183 may be positioned at a lower level than the lower surface of the second supporter 182 in the third direction DR3. A lower surface of the third supporter 183 may be positioned at a higher level than the upper surface of the lower structure 10 in the third direction DR3.

In various embodiments, the first supporter 181 may include the plurality of first openings 185_1 having a linear shape extending in the first direction DR1. The second supporter 182 may include the plurality of second openings 185_2 having a linear shape extending in the second direction DR2. The third supporter 183 may include a plurality of third openings 185_3 having a linear shape extending in the first direction DR1.

In various embodiments, the first supporter 181 may connect the plurality of lower electrodes 170 along the first direction DR1. The second supporter 182 may connect the plurality of lower electrodes 170 along the second direction DR2. The third supporter 183 may connect the plurality of lower electrodes 170 along the first direction DR1.

FIG. 10 is a cross-sectional view taken along line A-A′ parallel to the second direction DR2. Referring to FIG. 10, the plurality of lower electrodes 170 may be arranged to be spaced apart from each other along the second direction DR2 on the lower structure 10. The second supporter 182 may be position between the plurality of lower electrodes 170 in the second direction DR2. A side surface of the second supporter 182 may contact the side surfaces of the plurality of lower electrodes 170 in the second direction DR2.

In various embodiments, the first openings 185_1 and the third openings 185_3 may be position between the plurality of lower electrodes 170 in the second direction DR2. The second supporter 182 may overlap the first openings 185_1 and the third openings 185_3 in the third direction DR3.

In various embodiments, the dielectric layer 190 may cover the upper surfaces and the side surfaces of the plurality of lower electrodes 170. The dielectric layer 190 may cover the upper surface of the lower structure 10 positioned between the plurality of lower electrodes 170. The dielectric layer 190 may cover the upper surface and the lower surface of the second supporter 182. The dielectric layer 190 may extend from the side surfaces of the plurality of lower electrodes 170 onto the upper surface and the lower surface of the second supporter 182.

In various embodiments, the upper electrode 200 may be positioned on the dielectric layer 190. The upper electrode 200 may be spaced apart from the lower electrode 170, the second supporter 182, and the lower structure 10 interposing the dielectric layer 190. For example, the upper electrode 200 may overlap the upper surfaces and the side surfaces of the plurality of lower electrodes 170, the upper surface and the lower surface of the second supporter 182, and the upper surface of the lower structure 10 interposing the dielectric layer 190.

FIG. 11 is a cross-sectional view taken along line B-B′ parallel to the first direction DR1. Referring to FIG. 11, the plurality of lower electrodes 170 may be arranged to be spaced apart from each other along a first direction DR1 on the lower structure 10. The first supporter 181 and the third supporter 183 may be position between the plurality of lower electrodes 170 in the first direction DR1. In various embodiments, the side surface of the first supporter 181 and a side surface of the third supporter 183 may contact the side surfaces of the plurality of lower electrodes 170 in the first direction DR1.

In various embodiments, the second openings 185_2 may be position between the plurality of lower electrodes 170 in the first direction DR1. The first supporter 181 and the third supporter 183 may overlap the second openings 185_2 in the third direction DR3.

In various embodiments, the dielectric layer 190 may cover the upper surfaces and the side surfaces of the plurality of lower electrodes 170. The dielectric layer 190 may cover the upper surface of the lower structure 10 positioned between the plurality of lower electrodes 170. The dielectric layer 190 may cover upper surfaces and lower surfaces of the first supporter 181 and the third supporter 183. The dielectric layer 190 may extend from the side surfaces of the plurality of lower electrodes 170 onto the upper surfaces and the lower surfaces of the first supporter 181 and the third supporter 183.

In various embodiments, the upper electrode 200 may be positioned on the dielectric layer 190. The upper electrode 200 may be spaced apart from the lower electrode 170, the first supporter 181, the third supporter 183, and the lower structure 10 interposing the dielectric layer 190. For example, the upper electrode 200 may overlap the upper surfaces and the side surfaces of the plurality of lower electrodes 170, the upper surfaces and the lower surfaces of the first supporter 181 and the third supporter 183, and the upper surface of the lower structure 10 interposing the dielectric layer 190.

FIG. 12 is a cross-sectional view taken along line C-C′ parallel to the second direction DR2. Referring to FIG. 12, the first supporter 181 may include the plurality of first openings 185_1 having a linear shape extending in the first direction DR1. In various embodiments, the plurality of first openings 185_1 may penetrate the first supporter 181 in the third direction DR3. The first supporter 181 may include portions spaced apart along the second direction DR2 by the plurality of first openings 185_1. The portions of the first supporter 181 may be positioned between the lower electrodes 170 neighboring in the first direction DR1 in a plan view.

In various embodiments, the third supporter 183 may include the plurality of third openings 185_3 having a linear shape extending in the first direction DR1. The plurality of third openings 185_3 may penetrate the third supporter 183 in the third direction DR3. The third supporter 183 may include portions spaced apart along the second direction DR2 by the plurality of third openings 185_3. The portions of the first supporter 181 may be positioned between the lower electrodes 170 neighboring in the first direction DR1 in a plan view.

In various embodiments, the first supporter 181 and the third supporter 183 may overlap in the third direction DR3. The plurality of first openings 185_1 and the plurality of third openings 185_3 may overlap in the third direction DR3.

In various embodiments, the second opening 185_2 of the second supporter 182 may be positioned between the first supporter 181 and the third supporter 183 in the third direction DR3. The second opening 185_2 may penetrate the second supporter 182 in the third direction DR3. The second opening 185_2 may have a linear shape extending in the second direction DR2.

In various embodiments, the dielectric layer 190 may cover upper surfaces and lower surfaces of the portions of the first supporter 181 separated by the first openings 185_1 separated along the second direction DR2. The dielectric layer 190 may cover upper surfaces and lower surfaces of portions of the third supporter 183 separated by the third openings 185_3 separated along the second direction DR2.

In various embodiments, the dielectric layer 190 may cover portions of the side surface of the first supporter 181 positioned on both sides of the first openings 185_1. The dielectric layer 190 may extend from upper surface and the lower surface of the first supporter 181 onto the side surface of the first supporter 181 exposed by the first openings 185_1. The dielectric layer 190 may cover side surfaces of the portions of the third supporter 183 positioned on both sides of the third openings 185_3. The dielectric layer 190 may extend from an upper surface and a lower surface of the third supporter 183 onto the side surface of the third supporter 183 exposed by the third openings 185_3. The dielectric layer 190 may cover the upper surface of the lower structure 10.

In various embodiments, the upper electrode 200 may be positioned on the dielectric layer 190. The upper electrode 200 may be spaced apart from the first supporter 181, the third supporter 183, and the lower structure 10 interposing the dielectric layer 190. For example, the upper electrode 200 may overlap the upper surface, the lower surface, and the side surface of the first supporter 181 and the third supporter 183, and the upper surface of the lower structure 10 interposing the dielectric layer 190.

FIG. 13 is a cross-sectional view taken along line D-D′ parallel to the first direction DR1. Referring to FIG. 13, the second supporter 182 may include the plurality of second openings 185_2 having a linear shape extending in the second direction DR2. In various embodiments, the plurality of second openings 185_2 may penetrate the second supporter 182 in the third direction DR3. The second supporter 182 may include portions spaced apart along the first direction DR1 by the plurality of second openings 185_2. The portions of the second supporter 182 may be positioned between the lower electrodes 170 neighboring in the second direction DR2 in a plan view.

In various embodiments, the first opening 185_1 of the first supporter 181 and a third opening 185_3 of the third supporter 183 may be positioned to be spaced apart from the second supporter 182 in the third direction DR3. The first opening 185_1 may be positioned above the second supporter 182 in the third direction DR3. The third opening 185_3 may be positioned below the second supporter 182 in the third direction DR3.

In various embodiments, the first opening 185_1 and the third opening 185_3 may be positioned on both sides of the second supporter 182 in the third direction DR3. The first opening 185_1 may penetrate the first supporter 181 in the third direction DR3. The third opening 185_3 may penetrate the third supporter 183 in the third direction DR3. The first opening 185_1 and the third opening 185_3 may have a linear shape extending in the first direction DR1. The first opening 185_1 and the third opening 185_3 may overlap in the third direction DR3.

In various embodiments, the dielectric layer 190 may cover the upper surfaces and the lower surfaces of the portions of the second supporter 182 separated by the second openings 185_2 separated along the first direction DR1. The dielectric layer 190 may cover side surfaces of the portions of the second supporter 182 positioned on both sides of the second openings 185_2. The dielectric layer 190 may extend from the upper surface and the lower surface of the second supporter 182 onto the side surface of the second supporter 182 exposed by the second openings 185_2. The dielectric layer 190 may cover the upper surface of the lower structure 10.

In various embodiments, the upper electrode 200 may be positioned on the dielectric layer 190. The upper electrode 200 may be spaced apart from the second supporter 182 and the lower structure 10 interposing the dielectric layer 190. For example, the upper electrode 200 may overlap the upper surface, the lower surface, and the side surface of the second supporter 182, and the upper surface of the lower structure 10 interposing the dielectric layer 190.

In various embodiments, the capacitor structure 100 according to the embodiment described above with reference to FIG. 9 to FIG. 13 has three supporters 180, but is not limited thereto. In another embodiment, the number of supporters 180 may be two. Referring to FIG. 14, the capacitor structure 100 according to another embodiment may include the first supporter 181 and the second supporter 182 that are spaced apart in the third direction DR3.

In various embodiments, the upper surface of the first supporter 181 may be positioned at a lower level than the upper surface of the plurality of lower electrodes 170 in the third direction DR3. The upper surface of the second supporter 182 may be positioned at a lower level than the lower surface of the first supporter 181 in the third direction DR3. The lower surface of the second supporter 182 may be positioned at a higher level than the upper surface of the lower structure 10 in the third direction DR3.

In various embodiments, the first supporter 181 may include the plurality of first openings 185_1 having a linear shape extending in the first direction DR1. The second supporter 182 may include the plurality of second openings 185_2 having a linear shape extending in the second direction DR2. The first opening 185_1 may contact the both sides of the lower electrodes 170 neighboring in the second direction DR2. The second opening 185_2 may contact the both sides of the lower electrodes 170 neighboring in the first direction DR1.

In various embodiments, the first supporter 181 may connect the plurality of lower electrodes 170 along the first direction DR1. The second supporter 182 may connect the plurality of lower electrodes 170 along the second direction DR2. The first supporter 181 may include supporters of a rod shape extending in the first direction DR1. The second supporter 182 may include supporters of a rod shape extending in the second direction DR2.

In addition to the description above, the contents with respect to the first supporter 181 and the second supporter 182 described above with reference to FIG. 9 to FIG. 13 may be equally applied to the first supporter 181 and the second supporter 182 shown in FIG. 14.

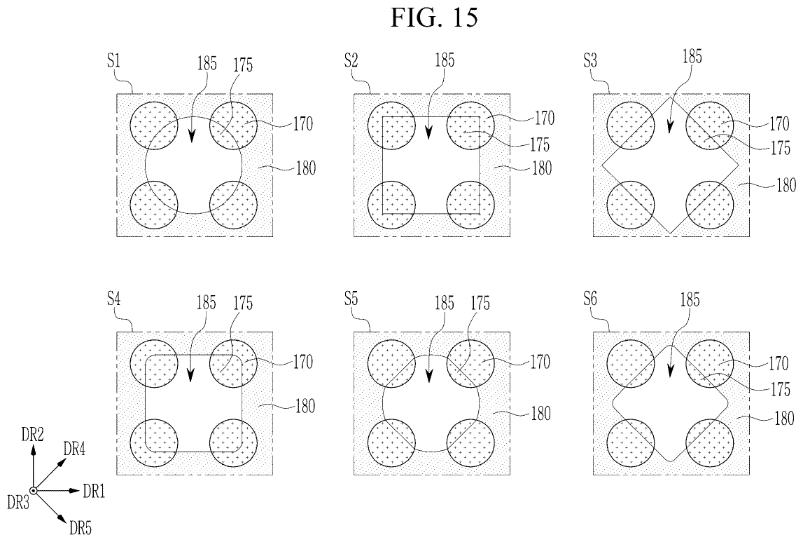

FIG. 15 is a drawing showing various examples of a planar shape of the opening 185 of the supporter 180. The planar shape of the opening 185 shown in FIG. 15 may be applied to the capacitor structure 100 shown in FIG. 1 or FIG. 5.

Referring to FIG. 15, the supporter 180 may surround the four lower electrodes 170 disposed at vertex positions of a quadrangle on a plane parallel to the second direction DR2 crossing the first direction DR1 and the first direction DR1 (e.g., a lattice structure). Each of the lower electrodes 170 may extend in the third direction DR3 perpendicular to the first direction DR1 and the second direction DR2. The supporter 180 may have a thickness in the third direction DR3. The opening 185 of the supporter 180 may contact the four lower electrodes 170. The opening 185 may contact a portion a side surface of the four lower electrodes 170.

Referring to a first shape S1, a planar shape of the opening 185 may be circular. Referring to a second shape S2 and a third shape S3, a planar shape of the opening 185 may be a quadrangle. Referring to a fourth shape S4, a fifth shape S5, and a sixth shape S6, a planar shape of the opening 185 may be a quadrangle with rounded corners.

In order to form the opening 185 having the first shape S1 in the supporter 180, a mask pattern may be formed on the plurality of lower electrodes 170 and the supporter 180 in the third direction DR3. The mask pattern may include circular mask openings arranged in the first direction DR1 and the second direction DR2. The mask openings may be positioned corresponding to and aligned with the pattern of the openings 185 FIG. 1 or FIG. 5. An etching process for etching the supporter 180 by using the mask pattern may be performed. The supporter 180 may include a material having a high etch selectivity with respect to the lower electrode 170. By the etching process, the opening 185 penetrating the supporter 180 in the third direction DR3 and having a circular planar shape may be formed. The upper surfaces of the lower electrodes 170 may also partially etched by the etching process, and accordingly, an upper surface of the four lower electrodes 170 contacting the opening 185 may partially include an inclined surface 175. The planar shape of the inclined surfaces 175 may be a part of the circular planar shape of the opening 185.

In various embodiments, the process of forming the opening 185 of the first shape S1 described above, may be the same as the process of forming the openings 185 of the second shape S2 to the sixth shape S6, except for the mask pattern.

In various embodiments, the mask pattern for forming the opening 185 of the second shape S2 may include quadrangular mask openings arranged in the first direction DR1 and the second direction DR2. The mask openings may be positioned corresponding to the pattern of the openings 185 FIG. 1 or FIG. 5. By the etching process, the opening 185 penetrating the supporter 180 in the third direction DR3 and having a quadrangular planar shape may be formed. The upper surfaces of the lower electrodes 170 may also partially etched by the etching process, and accordingly, the upper surface of the four lower electrodes 170 contacting the opening 185 may partially include the inclined surface 175. The quadrangular planar shape of the opening 185 may extend above the inclined surfaces 175. In this case, the shape of portions adjacent to the four vertexes of the quadrangle may appear on the inclined surfaces 175.

In various embodiments, the mask pattern for forming the opening 185 of the third shape S3 may include quadrangular mask openings arranged in the first direction DR1 and the second direction DR2. The mask openings may be positioned corresponding to the pattern of the openings 185 FIG. 1 or FIG. 5. By the etching process, the opening 185 penetrating the supporter 180 in the third direction DR3 and having a quadrangular planar shape may be formed. Four sides of the quadrangle may be parallel to the fifth direction DR5 crossing (e.g., perpendicularly) the fourth direction DR4 or the fourth direction DR4 oblique to the first direction DR1 and the second direction DR2. The upper surfaces of the lower electrodes 170 may also partially etched by the etching process, and accordingly, the upper surface of the four lower electrodes 170 contacting the opening 185 may partially include the inclined surface 175. The quadrangular planar shape of the opening 185 may extend above the inclined surfaces 175. In this case, the shape of portions adjacent to the four vertexes of the quadrangle may appear as the planar shape of the opening 185.

In various embodiments, the mask pattern for forming the opening 185 of the fourth shape S4 may be partially different from the mask pattern for forming the opening 185 of the second shape S2 only in the planar shape of the mask opening. A planar shape of the mask opening for forming the opening 185 of the fourth shape S4 may be a quadrangle with rounded corners. The mask openings may be positioned corresponding to the pattern of the openings 185 FIG. 1 or FIG. 5. By the etching process, the opening 185 penetrating the supporter 180 in the third direction DR3 and having a planar shape of a quadrangle with rounded corners may be formed. The upper surfaces of the lower electrodes 170 may also partially etched by the etching process, and accordingly, the upper surface of the four lower electrodes 170 contacting the opening 185 may partially include the inclined surface 175. The quadrangular planar shape with rounded corners of the opening 185 may extend above the inclined surfaces 175. In this case, the shape of portions adjacent to the rounded corner of the quadrangle may appear on the inclined surfaces 175.

In various embodiments, the mask pattern for forming the opening 185 of the fifth shape S5 or the sixth shape S6 may be partially different from the mask pattern for forming the opening 185 of the third shape S3 only in the planar shape of the mask opening. A planar shape of the mask opening for forming the opening 185 of the fifth shape S5 or the sixth shape S6 may be a quadrangle with rounded corners. The mask openings may be positioned corresponding to the pattern of the openings 185 FIG. 1 or FIG. 5. By the etching process, the opening 185 penetrating the supporter 180 in the third direction DR3 and having a planar shape of a quadrangle with rounded corners may be formed. Four sides of the quadrangle with rounded corners may be parallel to the fifth direction DR5 crossing (e.g., perpendicularly) the fourth direction DR4 or the fourth direction DR4 oblique to the first direction DR1 and the second direction DR2. The upper surfaces of the lower electrodes 170 may also partially etched by the etching process, and accordingly, the upper surface of the four lower electrodes 170 contacting the opening 185 may partially include the inclined surface 175. The quadrangular planar shape with rounded corners of the opening 185 may extend above the inclined surfaces 175. In this case, the shape of portions adjacent to the rounded corner of the quadrangle may appear as the planar shape of the opening 185. A curvature of a rounded corner in the opening 185 of the sixth shape S6 may be larger than a curvature of a rounded corner in the opening 185 of the fifth shape S5.

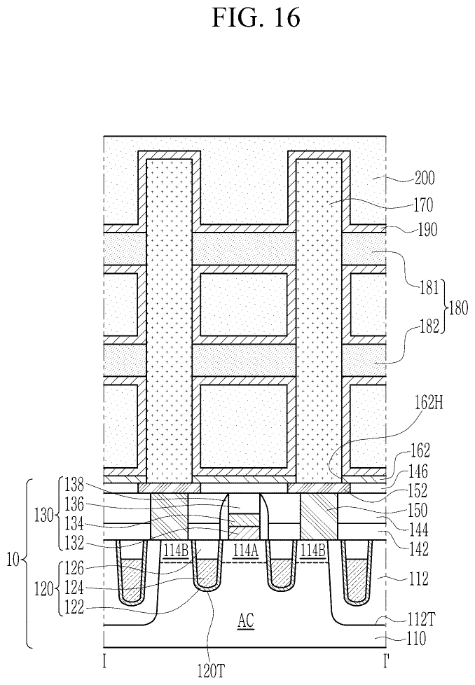

FIG. 16 is an example of a cross-sectional view taken along line I-I′ of FIG. 1. While FIG. 16 shows an example of the lower structure 10 where a semiconductor device including the capacitor structure 100 is a DRAM, a configuration and structure of the lower structure 10 is not limited thereto, and, may vary depending on the type of a semiconductor device including the capacitor structure 100. Configurations of the capacitor structure 100 that is, the lower electrode 170, the supporter 180, the dielectric layer 190, and the upper electrode 200 will be described below, focusing on contents that may be seen from the cross-section taken along line I-I′, and the contents described above with reference to FIG. 1, FIG. 2, FIG. 3A, and FIG. 4A may be equally applied in addition to contents described below.

In various embodiments, the description of the lower structure 10 below may be equally applied to the lower structure 10 connected to the capacitor structure 100 of FIG. 8 or the capacitor structure 100 of FIG. 5.

Referring to FIG. 16, the lower structure 10 may include a substrate 110. In various embodiments, the substrate 110 may be provided with an active region AC defined by an isolation layer 112. In various embodiments, the substrate 110 may include a semiconductor material such as Si, Ge, or SiGe, SiC, GaAs, InAs, or InP. In some embodiments, the substrate 110 may include a conductive region, for example, a well doped with impurities, or a region doped with impurities.

In various embodiments, the isolation layer 112 may have a shallow trench isolation (STI) structure, where for example, the isolation layer 112 may include an insulation material filling a device isolation trench 112T formed within the substrate 110. The insulation material may include, but not be limited to, FSG (Fluoride silicate glass), USG (Undoped silicate glass), BPSG (Boro-Phospho-silicate glass), PSG (Phospho-silicate glass), FOX (Flowable Oxide), PE-TEOS (Plasma Enhanced Tetra-Ethyl-Ortho-Silicate), or TOSZ (Tonen Silazene), and may be varied.

In various embodiments, P-type or N-type impurities may be doped in the active region AC.

In various embodiments, a gate line trench 120T may cross the active region AC, and may be formed to a predetermined depth from the upper surface of the substrate 110 in the third direction DR3 that is a vertical direction. A portion of the gate line trench 120T may extend into the isolation layer 112, where a portion of the gate line trench 120T formed within the isolation layer 112 may have a bottom surface that is positioned at a lower level than a portion of the gate line trench 120T formed within the active region AC.

In various embodiments, a first source/drain region 114A and a second source/drain region 114B may be formed in an upper region of the active region AC and positioned on both sides of the gate line trench 120T. The first source/drain region 114A and the second source/drain region 114B may be between adjacent pairs of the gate line trenchs 120T. The first source/drain region 114A and the second source/drain region 114B may be regions doped with impurities having conductivity types different from that of the impurities doped in the active region AC. For example, N-type or P-type impurities may be doped in the first source/drain region 114A and the second source/drain region 114B.

In various embodiments, a gate structure 120 may be positioned inside the gate line trench 120T. The gate structure 120 may include a gate insulation layer 122, a gate electrode 124, and a gate capping layer 126 sequentially formed on an inner wall of the gate line trench 120T.

In various embodiments, the gate insulation layer 122 may be conformally formed on the inner wall of the gate line trench 120T to a predetermined thickness. The gate insulation layer 122 may be formed of at least one material selected from high-k material having a higher dielectric constant than silicon oxide, silicon nitride, silicon nitride oxide, oxide/nitride/oxide (ONO), or silicon oxide. For example, the gate insulation layer 122 may have a dielectric constant of about 10 to about 25. In various embodiments, the gate insulation layer 122 may be made of HfO₂, ZrO₂, Al₂O₃, HfAlO₃, Ta₂O₃, TiO₂, or a combination thereof, but is not limited to the examples, and may be variously modified.

In various embodiments, the gate electrode 124 may be formed on the gate insulation layer 122 to a predetermined height from a bottom portion of the gate line trench 120T in the third direction DR3. In some embodiments, the gate electrode 124 may include a work function control layer disposed on the gate insulation layer 122 and a buried metal layer filling the bottom portion of the gate line trench 120T on the work function control layer. For example, the work function control layer may include a metal, a metal nitride, or a metal carbide, such as, Ti, TiN, TiAlN, TiAlC, TiAlCN, TiSiCN, Ta, TaN, TaAlN, TaAlCN, or TaSiCN, and the buried metal layer may include at least one of W, WN, TiN, or TaN.

In various embodiments, the gate capping layer 126 may fill a remaining portion of the gate line trench 120T on the gate electrode 124. The gate capping layer 126 may include at least one of silicon oxide, silicon nitride oxide, or silicon nitride.

In various embodiments, a bit line structure 130 extending along the second direction DR2 parallel to an upper surface of the substrate 110 and perpendicular to the first direction DR1 may be formed on the first source/drain region 114A. The bit line structure 130 may include a bit line contact 132, a bit line 134, a bit line capping layer 136, and a bit line spacer 138 sequentially accumulated on the substrate 110. A third insulation layer 146 may be on the bit line spacer 138. The bit line contact 132 may electrically connect the bit line 134 with the first source/drain region 114A. The bit line contact 132 may be between the bit line 134 and the first source/drain region 114A. The bit line contact 132 may be generally circular, but is not limited thereto, and the planar shape of the bit line contact 132 may be modified. The bit line contact 132 and the bit line 134 may each include conductive materials. For example, the bit line contact 132 may include polysilicon, and the bit line 134 may include a metal material.

In various embodiments, the bit line capping layer 136 may include an electrical insulation material, such as silicon nitride or silicon nitride oxide. The bit line spacer 138 may have a single-layer structure or a multi-layer structure formed of an electrical insulation material, such as silicon oxide, silicon nitride oxide, or silicon nitride.

In various embodiments, the bit line spacer 138 may further include an air space or air gap. A bit line intermediate layer may be interposed between the bit line contact 132 and the bit line 134. The bit line intermediate layer may include a metal silicide, such as tungsten silicide or a metal nitride such as tungsten nitride.

Although FIG. 16 illustrates that the bit line contact 132 has a bottom surface at the same level as the upper surface of the substrate 110, the embodiments are not limited thereto, and a recess of a predetermined depth may be formed on the upper surface of the substrate 110, the bit line contact 132 extends into the recess, and thereby a bottom surface of the bit line contact 132 may be formed at a lower level than the upper surface of the substrate 110.

In various embodiments, a first insulation layer 142 and a second insulation layer 144 may be sequentially formed on the substrate 110, and the bit line structure 130 may be formed in the first insulation layer 142 and the second insulation layer 144, where the bit line structure 130 may extend through the first insulation layer 142 and the second insulation layer 144, and be electrically connected to the first source/drain region 114A.

In various embodiments, a capacitor contact 150 may be positioned on the substrate 110, where the capacitor contact 150 may be formed on the second source/drain region 114B. A side surface of the capacitor contact 150 may be surrounded by the first insulation layer 142 and the second insulation layer 144. In various embodiments, the capacitor contact 150 may include a lower contact pattern, a metal silicide layer, and an upper contact pattern that are sequentially formed on the substrate 110, and may also include a barrier layer surrounding a side surface and a bottom surface of the upper contact pattern.

In various embodiments, the lower contact pattern may include polysilicon, and the upper contact pattern may include a metal material. The barrier layer may include a metal nitride having conductivity.

On the second insulation layer 144, a third insulation layer 146 may be formed, and a landing pad 152 penetrating the third insulation layer 146 and electrically connected to the capacitor contact 150 may be formed. As shown in FIG. 16, the landing pad 152 may overlap the entire capacitor contact 150 in the third direction DR3, and may be formed to have larger width than the capacitor contact 150. The landing pad 152 may include at least one of a metal, such as, ruthenium (Ru), titanium (Ti), tantalum (Ta), niobium (Nb), iridium (Ir), molybdenum (Mo), tungsten (W), or a conductive metal nitride, such as, titanium nitride (TiN), tantalum nitride (TaN), niobium nitride (NbN), molybdenum nitride (MoN), tungsten nitride (WN). In addition, in some embodiments, the landing pad 152 may include titanium nitride (TiN).

An etch stop layer 162 may be formed on the landing pad 152 and the third insulation layer 146. The etch stop layer 162 may include an opening 162H overlapping at least a portion of the landing pad 152. The etch stop layer 162 may include, for example, at least one of silicon nitride (SiN), silicon carbonitride (SiCN), silicon boronnitride (SiBN), silicon oxycarbide (SiCO), silicon nitride oxide (SiON), silicon oxide (SiO), or silicon carbonate nitride (SiOCN).

In various embodiments, the capacitor structure 100 may be disposed on the etch stop layer 162. The capacitor structure 100 may include the lower electrode 170 electrically connected to the capacitor contact 150 with the landing pad 152 therebetween, the supporter 180 on both lateral sides of the lower electrode 170, the dielectric layer 190 conformally covering the lower electrode 170, and the upper electrode 200 on the dielectric layer 190.

As shown in FIG. 1, the lower electrode 170 may be repeatedly arranged along the first direction DR1 and the second direction DR2 in an array. The capacitor contact 150 and the landing pad 152 may overlap the lower electrode 170 in the third direction DR3, and may be spaced apart in the first direction DR1 and the second direction DR2 to be arranged in a matrix shape.

In various embodiments, the lower electrode 170 may be disposed on the landing pad 152, and a bottom portion of the lower electrode 170 may be disposed within the opening 162H in the etch stop layer 162. A width (diameter) of the bottom portion of the lower electrode 170 may be smaller than a width (diameter) of the landing pad 152, where the entire bottom surface of the lower electrode 170 may contact the landing pad 152.

In various embodiments, the lower electrode 170 may have a pillar or column shape extending in the third direction DR3, but is not limited thereto. In another embodiment, the lower electrode 170 may be formed in the shape of a closed cylinder or cup on the landing pad 152.

In various embodiments, the supporters 180 may be on both sides of the lower electrode 170. The supporter 180 may include, for example, a first supporter 181 and a second supporter 182 spaced apart in the third direction DR3. The first supporter 181 may be disposed on both lateral sides positioned in an upper portion of the lower electrode 170. The second supporter 182 may be disposed on both lateral sides positioned in a central portion of the lower electrode 170.

In various embodiments, the supporter 180 may be disposed between the lower electrode 170 and another lower electrode 170 adjacent thereto. The first supporter 181 may contact upper side surfaces of the adjacent lower electrodes 170. The second supporter 182 may contact central portion side surfaces of the adjacent lower electrodes 170.

As shown in FIG. 1, the supporter 180 may include the plurality of openings 185. For detailed description on the plurality of openings 185, refer to the contents described with reference to FIG. 1, FIG. 2, FIG. 3A, and FIG. 4A.

In various embodiments, the dielectric layer 190 may be disposed on the side surface and the and upper surface of the lower electrode 170. The dielectric layer 190 may extend from the side surface of the lower electrode 170 onto the upper surface and the lower surface of the supporter 180, and may also be disposed on the etch stop layer 162.

In various embodiments, the upper electrode 200 covering the lower electrode 170 may be disposed on the dielectric layer 190. The upper electrode 200 may be formed as a single material layer or in a stacking structure of layers of a plurality of materials. For example, the upper electrode 200 may be formed of a single layer of titanium nitride (TiN) or a single layer of niobium nitride (NbN). As another example, the upper electrode 200 may be formed as a stacking structure of a first upper electrode layer containing titanium nitride (TiN) and a second upper electrode layer containing niobium nitride (NbN).

While the embodiment of the present disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A capacitor structure, comprising:
a plurality of lower electrodes arranged in a first direction and a second direction perpendicular to the first direction;
a supporter including a plurality of openings and adjoining the plurality of lower electrodes;
a dielectric layer covering the supporter and the plurality of lower electrodes; and
an upper electrode covering the dielectric layer,
wherein each of the plurality of openings contacts four lower electrodes, and
wherein the plurality of openings contact opposite sides of the plurality of lower electrodes along the first direction and the second direction.

2. The capacitor structure of claim 1, wherein the supporter surrounds one or more of the plurality of lower electrodes.

3. The capacitor structure of claim 2, wherein the lower electrodes surrounded by the supporter are spaced apart from each other in the first direction and the second direction, and four lower electrodes contacting the plurality of openings are disposed between the lower electrodes surrounded by the supporter.

4. The capacitor structure of claim 2, wherein the plurality of openings are arranged and spaced apart in the first direction and the second direction, and six lower electrodes are disposed between the lower electrodes contacting each of the parallel openings in the first direction or the second direction.

5. The capacitor structure of claim 1, wherein each of the plurality of lower electrodes contacts at least one opening.

6. The capacitor structure of claim 5, wherein the plurality of openings are arranged and spaced apart in the first direction and the second direction, and no lower electrodes are disposed between the lower electrodes contacting each of the parallel openings in the first direction or the second direction.

7. The capacitor structure of claim 5, wherein the plurality of openings are arranged to commonly contact one lower electrode in a third direction oblique with respect to the first direction and the second direction and a fourth direction perpendicular to the third direction.

8. The capacitor structure of claim 5, wherein:
the supporter includes portions positioned between four lower electrodes having a quadrangular arrangement;
the portions include a first portion and a second portion that are adjacent along the first direction or the second direction; and
the first portion and the second portion are separated by the one opening.

9. The capacitor structure of claim 1, wherein a planar shape of the plurality of openings is a circle, a quadrangle, or a quadrangle with rounded corners.

10. A capacitor structure, comprising:
a plurality of lower electrodes horizontally arranged in a first direction and a second direction perpendicular to the first direction;
a plurality of supporters adjoining the plurality of lower electrodes and spaced apart in a third direction perpendicular to the first direction and the second direction;
a dielectric layer covering the plurality of supporters and the plurality of lower electrodes; and
an upper electrode covering the dielectric layer,
wherein the plurality of supporters include a plurality of openings penetrating along the third direction,
wherein each of the plurality of openings contacts four lower electrodes,
wherein the plurality of openings contact opposite sides of rows of lower electrodes arranged along the first direction, and contact opposite sides of columns of lower electrodes arranged along the second direction, and
wherein a pattern of the plurality of openings included in each supporter overlaps in the third direction.

11. The capacitor structure of claim 10, further comprising a plurality of lower electrodes that do not contact the openings, wherein the plurality of lower electrodes that do not contact the openings are arranged along the first direction and the second direction, and four lower electrodes contacting an opening are between an adjacent pair of lower electrodes that do not contact the openings.

12. The capacitor structure of claim 11, wherein:
the plurality of lower electrodes include a first lower electrode contacting a first opening and a second lower electrode contacting a second opening, and adjacent to each other; and
a direction from a center of a first opening contacting the first lower electrode to a center of the first lower electrode and a direction from a center of a second opening contacting the second lower electrode to a center of the second lower electrode are opposite to each other.

13. The capacitor structure of claim 10, wherein two lower electrodes neighboring in the first direction or the second direction commonly contact one opening.

14. The capacitor structure of claim 13, wherein:
the plurality of lower electrodes includes a third lower electrode contacting two openings; and
a direction from a center of a first opening contacting the third lower electrode to center of the third lower electrode and a direction from a center of a second opening contacting the third lower electrode to center of the third lower electrode are opposite to each other.

15. A capacitor structure, comprising:
a plurality of lower electrodes horizontally arranged in a first direction and a second direction perpendicular to the first direction;
a plurality of supporters adjoining the plurality of lower electrodes, and spaced apart in a third direction perpendicular to the first direction and the second direction;
a dielectric layer covering a plurality of supporters and the plurality of lower electrodes; and
an upper electrode covering the dielectric layer,
wherein the plurality of supporters includes a first supporter and a second supporter,
wherein the first supporter includes a plurality of first openings having a linear shape extending in the first direction, and
wherein the second supporter includes a plurality of second openings having a linear shape extending in the second direction.

16. The capacitor structure of claim 15, wherein:
the first opening contacts both sides of the lower electrodes neighboring in the second direction; and
the second opening contacts both sides of the lower electrodes neighboring in the first direction.

17. The capacitor structure of claim 15, wherein:
an interval between the first openings is shorter than a diameter of the lower electrode; and
an interval between the second openings is shorter than the diameter of the lower electrode.

18. The capacitor structure of claim 15, wherein a planar shape of the plurality of supporters is a mesh shape.

19. The capacitor structure of claim 15, wherein:
the first supporter connects the plurality of lower electrodes along the first direction; and
the second supporter connects the plurality of lower electrodes along the second direction.

20. The capacitor structure of claim 15, wherein the plurality of supporters alternately includes, in the third direction, supporters of a rod shape extending in the first direction and supporters of a rod shape extending in the second direction.
